(19) United States
(12) Patent Application Publication
(10) Pub. No.: US 2026/0291205 A1
(43) Pub. Date: Sep. 24, 2026

(54) SEMICONDUCTOR-BASED CIRCUIT BREAKER AND OPERATING METHOD

(71) Applicant: Siemens Aktiengesellschaft, München (DE)

(72) Inventors: Hauke Nannen, Amberg (DE); Karsten Handt, Amberg (DE)

(21) Appl. No.: 19/576,217

(22) Filed: Mar. 24, 2026

(30) Foreign Application Priority Data
Mar. 24, 2025 (DE) 10 2025 111 227.4

(51) Int. Cl. H02H 1/06; H02H 3/08

(52) U.S. Cl. CPC H02H 1/06; H02H 3/08

(57) ABSTRACT

A solid state circuit breaker having network-side connections and load-side connections. A main current path that conducts a main current between the network-side and the load-side connections. Two normally-on semiconductor actuators connected in antiseries in the main current path and each having a control connection for controlling the voltage of the normally-on semiconductor actuators. Two normally-off semiconductor actuators connected in antiseries in the main current path and each having a control connection for controlling the voltage of the normally-off semiconductor actuators. A charge store connected in parallel with the normally-off semiconductor actuators and being configured to be charged by blocking the main current by means of the normally-off semiconductor actuators. In the charged state, provides a supply voltage for operating the circuit breaker.

### CROSS-REFERENCE TO RELATED APPLICATION

This application claims the priority, under 35 U.S.C. § 119, of German Patent Application DE 10 2025 111 227.4, filed Mar. 24, 2025; the prior application is herewith incorporated by reference in its entirety.

### FIELD AND BACKGROUND OF THE INVENTION

The present invention relates to a semiconductor-based circuit breaker and to a method for operating such a circuit breaker.

Semiconductor-based circuit breakers, also referred to in the following description as "solid state circuit breakers" (=SSCB), are an alternative to electromechanical circuit breakers. SSCBs have at least one semiconductor actuator, such as a MOSFET, an IGBT, etc., and a control unit which, in the case of a fault event, for example in the case of an overcurrent or overload in a main circuit, causes the semiconductor actuator to change into a high-impedance switching state by controlling the semiconductor actuator. Often, an SSCB also has a current measuring apparatus (current sensor for short), by means of which a fault event in the main circuit can be detected. To supply energy to the control unit and to the at least one semiconductor actuator, a supply voltage is required and is either supplied to the SSCB from the outside ("external voltage supply") or is taken from the main circuit ("internal voltage supply"). If the supply voltage is taken from the main circuit, this is referred to as a self-supplied device, since no external voltage supply is required.

SSCBs in which normally off semiconductor actuators are used to interrupt the main circuit, i.e. semiconductor actuators which are electrically blocking in the voltage-free state, i.e. without the application of a control voltage, that is to say in a high-impedance switching state, are customary. An internal voltage supply for such an SSCB can be realized in a simple manner by using a voltage present across the semiconductor actuator in the normally off state of the semiconductor actuator for the voltage supply for the SSCB.

Normally on semiconductor actuators, that is to say semiconductor actuators which are electrically conducting in the voltage-free state, that is to say without the application of a control voltage, that is to say in a low-impedance switching state, have some advantages over normally off semiconductor actuators. Therefore, there is a demand for SSCs in which normally on semiconductor actuators are used to interrupt the main circuit. However, since no voltage builds up by itself across a normally on semiconductor actuator, self-supply of an SSC in which normally on semiconductor actuators are used to interrupt the main circuit is problematic.

### SUMMARY OF THE INVENTION

One object of the present invention is to provide a self-supply of an SSCB which has normally on semiconductor actuators for interrupting a main circuit.

This object is achieved by a circuit breaker as claimed. This object is also achieved by a method for operating a circuit breaker as claimed. The object is also achieved by a computer program product as claimed.

One aspect of the invention is a solid state circuit breaker; "semiconductor-based" means that the circuit breaker uses at least one semiconductor actuator to perform its protective and switching tasks. The circuit breaker has network-side connections and load-side connections. The circuit breaker has a main current path which electrically connects the network-side and load-side connections. The main current path is used to conduct a main current from the network-side to the load-side connections. The main current path, which is preferably guided through a housing of the circuit breaker, forms a section of a main circuit if the circuit breaker is connected into a main circuit by way of its network-side connections and load-side connections.

The term "main current" should be interpreted broadly: it comprises any current through the main current path, that is to say, on the one hand, a load current for electrically supplying an electrical load such as a drive apparatus (e.g. electric motor), a heating apparatus (e.g. radiant heater), a lighting apparatus (e.g. light-emitting diodes) or a charge store (e.g. rechargeable battery, capacitor) with electrical energy from an electrical supply network, but, on the other hand, also a current along the main current path that flows from the load-side connections to the network-side connections, that is to say in a feedback situation that can occur in a bidirectional DC power supply which allows both energy to be fed from the network into a load zone and energy to be fed back into the network from a network section with an energy source (for example a photovoltaic system or a charged battery).

The circuit breaker has at least two normally on semiconductor actuators connected in antiseries in the main current path. The normally on semiconductor actuators each have a control connection, via which the voltage of the normally on semiconductor actuators can be controlled. The attribute "normally on" indicates that the normally on semiconductor actuators are in a low-impedance, i.e. electrically conducting, state if no voltage is applied to their control connection.

The circuit breaker also has at least two normally off semiconductor actuators connected in antiseries in the main current path. The normally off semiconductor actuators each have a control connection, via which the voltage of the normally off semiconductor actuators can be controlled. The attribute "normally off" indicates that the normally off semiconductor actuators are in a high-impedance, i.e. electrically non-conducting, state if no voltage is applied to their control connection.

The circuit breaker also has a charge store connected in parallel with the normally off semiconductor actuators. The charge store can be electrically charged by blocking the main current through the main current path by means of the normally off semiconductor actuators. In the charged state, the charge store provides a supply voltage for operating the circuit breaker.

The circuit breaker can be used in single-phase or multi-phase power networks: the main circuit can have one or more phases (= phase conductors). The circuit breaker has, in at least one main current path, a circuit comprising normally on semiconductor actuators, normally off semiconductor actuators and charge stores; as a rule, it has such a circuit in each of its one or more main current paths.

The following description relates to a single main current path; however, it is clear to a person skilled in the art that, in the case of a multi-phase main circuit, the circuit breaker can have one main current path per phase, all of which are of identical design. A voltage source of the low-voltage circuit is connected to the network-side connection, and an electrical consumer of the low-voltage circuit is connected to the load-side connection. The at least one current path thus forms a section of the low-voltage circuit. A semiconductor switch is arranged in the at least one current path.

A solid state circuit breaker may be present as one of various device types, e.g. as a circuit breaker, a motor starter, a relay, a contactor, etc. The power section of an SSCB usually comprises at least one semiconductor actuator per phase, for example a connection of a MOSFET, JFET, IGBT, or the like, and, in parallel with the semiconductor actuator, an energy absorber (= EA), for example a varistor, a TVS diode or an RC circuit. By limiting a voltage applied to the EA to an EA-specific clamping voltage U_{C}, the EA protects the semiconductor switch from damage caused by an overvoltage occurring during a switch-off process of the semiconductor switch (voltage-limiting function), and dissipates the energy (demagnetization energy) stored in the inductances of the circuit, e.g. in coils or in the line inductance, (energy-absorbing function). A common and relatively cost-effective variant is overvoltage protection with a metal oxide varistor (= MOV).

If the main current flowed through the circuit breaker on its main current path only in a single defined direction (unidirectional DC network), then a circuit comprising a normally on semiconductor actuator, a normally off semiconductor actuator and a charge store would suffice. For suitability of the circuit breaker in a bidirectional DC network or in an AC network, in which the main current on its main current path can take place in both directions, two pairs of the normally on semiconductor actuators and the normally off semiconductor actuators that are connected in antiseries must be present in each case.

FETs are voltage-controlled semiconductor actuators because the applied control voltage = gate-source voltage V_{GS} regulates the semiconductor resistance in order to thus switch or control the strength of an electrical current I_{DS} between the source and drain, which corresponds to the main current in this invention. JFETs are normally on semiconductor actuators, i.e. they are electrically conducting between the source and drain, when no control voltage is applied. MOSFETs are normally off semiconductor actuators, i.e. they are electrically blocking between the source and drain, when no control voltage is applied. MOSFETs manufactured in Si and SiC (enhancement type, normally OFF) are often chosen for circuit applications in the low and medium power range.

The invention is based on the finding that a self-supply of an SSCB, which has normally on semiconductor actuators for interrupting a main current, is possible by means of normally off semiconductor actuators which are connected in series with the normally on semiconductor actuators: a charge store connected in parallel with the normally off semiconductor actuators can be charged by the main current and, in the charged state, provides a voltage for supplying voltage to the SSCB.

Since only normally off semiconductor actuators (power semiconductors) have previously been used in SSCBs to interrupt a main current, the invention thus provides a novel solution which makes it possible to reliably interrupt a main current with normally on semiconductor actuators. The invention thus enables a self-supply of a solid state circuit breaker even when the main part of the blocking voltage is provided by semiconductor actuators which are conducting without a control voltage.

A further aspect of the invention is a method for operating a solid state circuit breaker, which has two normally on semiconductor actuators which are connected in antiseries in a main current path of the circuit breaker. In this case, the method has a step in which a main current is conducted through the main current path which electrically connects network-side and load-side connections of the circuit breaker, wherein the main current is caused by a voltage applied between the network-side connections and load-side connections. The method also has a step in which a charge store, which is connected in parallel with two normally off semiconductor actuators connected in antiseries in the main current path, is charged by way of the caused main current by blocking a main current by means of the normally off semiconductor actuators. The method also has a step in which a charged state of the charge store is reached, in which state it provides a supply voltage for operating the circuit breaker. The method also has a step in which the circuit breaker is operated by means of the supply voltage provided by the charge store.

A further aspect of the invention is a computer program product which can be loaded directly into the internal memory of a digital computing unit and comprises software code sections which cause the circuit breaker according to the invention to carry out the method steps of the method described herein when the product runs on the computing unit. The computing unit is in particular a computing unit for controlling the circuit breaker. The computer program product can be stored on a data carrier, such as a USB memory stick, a DVD or a CD-ROM, a flash memory, an EEPROM or an SD card (USB = Universal Serial Bus; DVD = Digital Versatile Disc; CD-ROM = Compact Disc-Read-Only Memory; EEPROM = Electrically Erasable Programmable Read-Only Memory; SD = Secure Digital). The computer program product can also be present in the form of a signal that can be loaded via a wired or wireless network.

The method is implemented for automatic execution, preferably in the form of a computer program. The invention is therefore on the one hand also a computer program having program code instructions that can be executed by a computer and on the other hand a storage medium having a computer program of this type, that is to say a computer program product having program code means, and finally also an energy source or a tertiary regulating unit, in the memory of which such a computer program is or can be loaded as means for carrying out the method and its configurations.

When method steps or sequences of method steps are described below, this relates to actions that take place owing to the computer program or under the control of the computer program insofar as it is not explicitly noted that individual actions are caused by a user of the computer program. At least, each use of the term “automatic” means that the relevant action takes place owing to the computer program or under the control of the computer program.

Instead of a computer program having individual program code instructions, the implementation of the method described here and below can also take place in the form of firmware. It is clear to a person skilled in the art that, instead of an implementation of a method in software, an implementation in firmware or in firmware and software or in firmware and hardware is also always possible. Therefore, it should be true for the description presented here that the term software or the term computer program also includes other implementation possibilities, namely in particular an implementation in firmware or in firmware and software or in firmware and hardware.

A further aspect of the invention is a computer-readable medium on which the computer program as claimed is stored.

Advantageous configurations and developments of the invention are specified in the dependent claims. In this case, the method according to the invention can also be developed according to the dependent apparatus claims, and vice versa.

According to one preferred configuration of the invention, the circuit breaker has a control unit for controlling the voltage of the semiconductor actuators, wherein the charge store, in the charged state, provides a supply voltage for the control unit and for controlling the voltage of the semiconductor actuators.

According to one preferred configuration of the invention, the normally off semiconductor actuators are connected between the normally on semiconductor actuators. In this connection, the two normally on semiconductor actuators are arranged around the normally off semiconductor actuators. As a result, the supply voltage generated in the charge store already has the correct potential reference for controlling the normally on semiconductor actuators: The reference point (ground) lies between the two normally on semiconductor actuators, such that their control connections (gate) can be controlled

According to one preferred configuration of the invention, the normally off semiconductor actuators and the normally on semiconductor actuators are each connected in series in pairs in antiseries. In pairs in antiseries means that the components are connected to one another directly in mirror-inverted fashion (drain to drain or source to source). However, in the case of this connection, which forms an alternative to the aforementioned connection, there is the problem that the supply voltage generated in the charge store has a fixed potential reference through the circuit. The reference point (ground) lies between the two normally off semiconductor actuators, but it should lie between the two normally on semiconductor actuators in order to be able to control their control connections (gate). If it is now desired to use the supply voltage generated in the charge store for control, further potential isolation is required, which means costs and effort. In addition, this potential isolation lowers the speed at which the supply voltage is present at the correct potential, for example by virtue of a delay in using an insulated DC-DC converter.

According to one preferred configuration of the invention, the circuit breaker has a current measuring apparatus in the main current path. The current measuring apparatus can either be in the form of a separate device, for example a current measuring resistor (= shunt), a Hall sensor, etc., or the current intensity in the main current path can be determined via a voltage drop across the semiconductor actuators.

According to one preferred configuration of the invention, the circuit breaker has at least one switching element, by means of which the charge store can be electrically connected to the control connections of the normally on semiconductor actuators or can be disconnected therefrom. Said switching element may be in the form of an electromechanical switch, for example a relay. Said switching element may alternatively be embodied as an electronic contact, e.g. a transistor, an optocoupler or combinations. The operating mode of the circuit breaker can be switched over by means of the switching element. If the switching element is in a conducting or low-impedance switching state, the normally on semiconductor actuators and the normally off semiconductor actuators are connected in a manner known in the literature as a cascode circuit: if the normally off semiconductor actuators are blocking, the normally on semiconductor actuators also enter a blocking state. If the switching element is in a blocking or high-impedance switching state, the normally on semiconductor actuators are in a permanently conducting state and the normally off semiconductor actuators can be controlled independently of the normally on semiconductor actuators.

According to one preferred configuration of the invention, the aforementioned at least one switching element, by means of which the charge store can be electrically connected to the control connections of the normally on semiconductor actuators or can be disconnected therefrom, can be actuated by the control unit. The switching element is preferably embodied as an electronic contact, e.g. a transistor, an optocoupler or combinations.

According to one preferred configuration of the invention, the normally on semiconductor actuators are HV transistors (HV = high voltage). An HV transistor is a transistor with a relatively high breakdown voltage. An example of an HV transistor is a JFET (= junction field-effect transistor).

According to one preferred configuration of the invention, the normally off semiconductor actuators are LV transistors (LV = low voltage). An LV transistor is a transistor with a relatively low breakdown voltage. An example of an LV transistor is a MOSFET (= metal oxide semiconductor field-effect transistor).

According to one preferred configuration of the invention, the normally off semiconductor actuators are low-voltage components. Low-voltage components are understood to mean components having a maximum blocking voltage of less than 85 volts.

According to one preferred configuration of the invention, the normally on semiconductor actuators are high-voltage components. High-voltage components are understood to mean components having a maximum blocking voltage of greater than or equal to 200 volts, preferably greater than or equal to 1000 volts.

According to one preferred configuration of the invention, in order to reduce losses in the conducting state of the normally on semiconductor actuators, a control connection which is controlled to control the voltage of the normally on semiconductor actuators is controlled with a positive gate-source voltage (for example +2 V), since JFETs often have the lowest on-state losses under these conditions.

According to one preferred configuration of the invention, the method has the following step: operating a control unit which is designed to control the voltage of the semiconductor actuators, and/or the two normally on semiconductor actuators and/or the two normally off semiconductor actuators by means of the supply voltage provided by the charge store.

According to one preferred configuration of the invention, the method has the following step: if the supply voltage drops below a defined critical threshold value, the normally off semiconductor actuators are brought from a conducting state into a blocking state in order to charge the charge store again above the threshold value.

According to one preferred configuration of the invention, the length of a period of time during which the normally off semiconductor actuators are in a blocking state for charging the charge store is selected on the basis of the main current and the loads connected to the charge store.

According to one preferred configuration of the invention, the normally on semiconductor actuators are connected to the normally off semiconductor actuators in a cascode circuit such that the normally on semiconductor actuators change to the blocking state as soon as the charge store has built up a supply voltage which is sufficient to control the normally on semiconductor actuators.

According to one preferred configuration of the invention, when a short-circuit current is detected in the main current path, the charge store charged to a supply voltage sufficient to control the normally on semiconductor actuators is electrically connected to control connections of the normally on semiconductor actuators by means of a switching element, such that the normally on semiconductor actuators change to the blocking state.

Other features which are considered as characteristic for the invention are set forth in the appended claims.

Although the invention is illustrated and described herein as embodied in a solid state circuit breaker and operating method, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

The above-described properties, features and advantages of this invention and the way in which they are achieved will become clearer and more clearly understandable from the following description of the exemplary embodiments, which are explained in more detail with reference to the drawings, in which, in each case schematically and not to scale,

### BRIEF DESCRIPTION OF THE FIGURES

FIG. 1 shows a circuit diagram of a circuit breaker, in which the normally off semiconductor actuators and the normally on semiconductor actuators are each connected in pairs in antiseries in series with one another;

FIG. 2 shows a circuit diagram of a circuit breaker, in which the normally off semiconductor actuators are connected in antiseries between the normally on semiconductor actuators;

FIG. 3 shows a simplified illustration of FIG. 2 for explaining the various operating modes described in FIGS. 4 to 9;

FIG. 4 shows an overview of different operating modes;

FIGS. 5-6 show processes when there is formation of the network and a significant load (= standard case);

FIG. 5 shows a process when there is formation of the network and a significant load: mode that immediately transitions to a conducting state: S1 is blocking;

FIG. 6 shows a process when there is formation of the network and a significant load: mode that transitions to a conducting state only after release: S1 is conducting;

FIG. 7 shows a process when there is formation of the network and no load (extreme case 1: no main current): both mode A and mode B;

FIGS. 8-9 show processes when there is formation of the network and a short circuit (extreme case 2: excessively high main current = short circuit);

FIG. 8 shows a process when there is formation of the network and a short circuit: mode that immediately transitions to a conducting state: S1 is blocking; and

FIG. 9 shows a process when there is formation of the network and a short circuit: mode that transitions to a conducting state only after release: S1 is conducting.

### DETAILED DESCRIPTION OF THE INVENTION

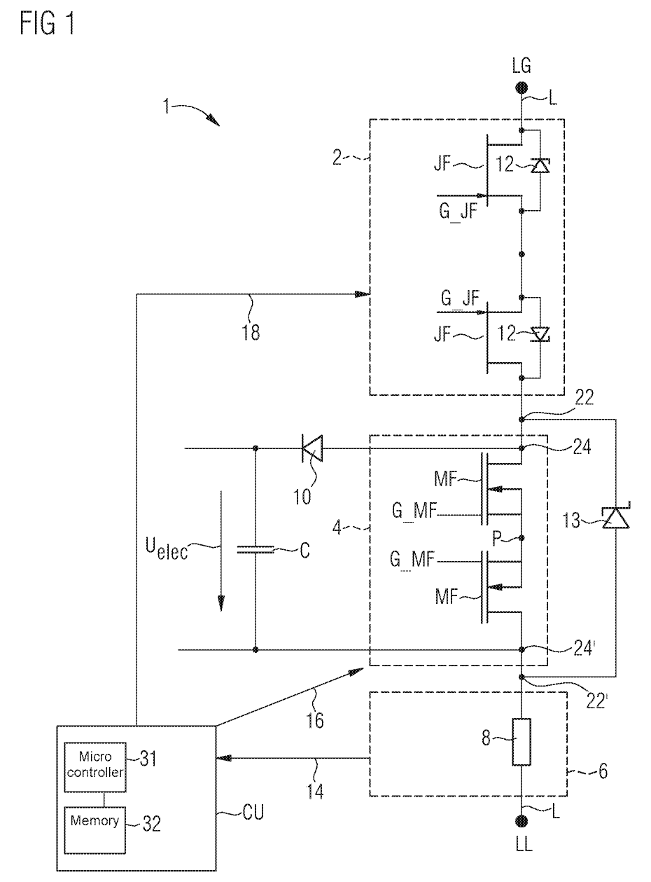

FIG. 1 is a circuit diagram of a circuit breaker 1. The circuit breaker 1 has network-side connections LG and load-side connections LL. These connections LG, LL can be designed, for example, as screw or plug connections, by means of which phase conductors can be electrically connected to the circuit breaker 1. The circuit breaker 1 has a main current path L for conducting a main current between the network-side and the load-side connections LG, LL.

The circuit breaker 1 has two normally on semiconductor actuators JF which are connected in antiseries in the main current path L and each have a control connection G_JF for controlling the normally on semiconductor actuators JF. The normally on semiconductor actuators JF are designed as JFETs. The two normally on semiconductor actuators JF form an HV switch 2.

The circuit breaker 1 has two normally off semiconductor actuators MF which are connected in antiseries in the main current path L and each have a control connection G_MF for controlling the normally off semiconductor actuators MF. The normally off semiconductor actuators MF are designed as MOSFETs. The two normally off semiconductor actuators MF form an LV switch 4.

The power electronics part of the circuit breaker 1 is thus separated into an HV part and an LV part. The HV part includes the JFETs JF and the LV part includes the MOSFETs MF. The normally off semiconductor actuators MF and the normally on semiconductor actuators JF are each connected in pairs in antiseries with one another, that is to say the HV switch 2 is arranged in the main current path L between the network-side connection LG and the LV switch 4.

The circuit breaker 1 has a charge store C in the form of a capacitor, which is connected in parallel with the normally off semiconductor actuators MF and can be charged by blocking the main current by means of the normally off semiconductor actuators MF and, in the charged state, provides a supply voltage U_{elec} for operating the circuit breaker 1. The charge store C is connected in parallel with the HV switch 2 having the normally on semiconductor actuators JF; in this case, the charge store C is connected to the main current path L at two contact points 24, 24' on both sides of the LV switch 4. In order to prevent discharge of the charge store C, a diode 10 is arranged in the electrical line that connects one pole of the charge store C to the main current path L.

The circuit breaker 1 has a control unit CU for controlling the voltage of the semiconductor actuators JF, MF. In this case, the charge store C, in the charged state, provides a supply voltage Uelec for the control unit CU and for controlling the voltage of the semiconductor actuators JF, MF. The control unit CU has a digital computing unit 31, for example a microprocessor, and a data memory 32 in which a computer program product is stored. The computer program product can be loaded directly into the internal memory of the digital computing unit 31; it comprises software code sections which cause the circuit breaker 1 according to the invention to carry out the method steps of the method described herein when the computer program product runs on the digital computing unit 31.

The circuit breaker 1 has a current measuring apparatus 6 in the main current path L. The current measuring apparatus 6 is arranged in the main current path L between the load-side connection LL and the LV switch 4. The current measuring apparatus 6 has a current measuring resistor 8. Current values determined by the current measuring apparatus 6 are transmitted to the control unit CU by way of a data transmission path 14. In the control unit CU, control commands for controlling the voltage of the semiconductor actuators JF, MF are generated on the basis of the received current values and are transmitted to the semiconductor actuators JF, MF by way of the control paths 16, 18. The voltage for operating the control unit CU and for controlling the voltage of the HV switch 2 and the LV switch 4 is provided by the supply voltage Uelec stored in the charge store C.

Connected in parallel with the LV switch 4 having the normally off semiconductor actuators MF is an avalanche diode 13 (bidirectional breakdown effect) which is connected to the main current path L at the two contact points 22, 22' on both sides of the LV switch 4. A unidirectional breakdown diode 12 is respectively connected in parallel with the normally on semiconductor actuators JF.

In the connection shown in FIG. 1, in which the normally off semiconductor actuators MF and the normally on semiconductor actuators JF are each connected in pairs in antiseries with one another, there is, however, the problem that the supply voltage Uelec generated in the charge store C has a fixed potential reference through the circuit. The potential reference point P (ground) lies between the two normally off semiconductor actuators MF, but it should lie between the two normally on semiconductor actuators JF in order to be able to control their control connections G_JF (gate). If it is now desired to use the supply voltage Uelec generated in the charge store C for control, further potential isolation is required, which means costs and effort. In addition, this potential isolation lowers the speed at which the supply voltage Uelec is present at the correct potential, for example by virtue of a delay caused by an insulated DC-DC converter.

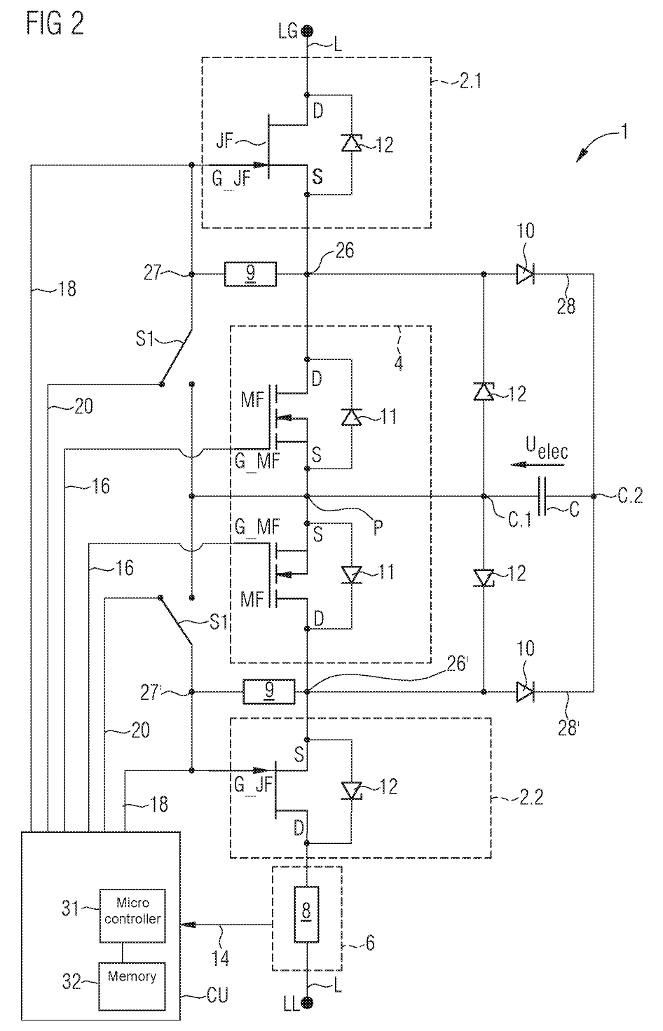

FIG. 2 shows an alternative circuit diagram of a circuit breaker 1. As in FIG. 1, the circuit breaker 1 has network-side connections LG and load-side connections LL. These connections LG, LL can be designed, for example, as screw or plug connections, by means of which phase conductors can be electrically connected to the circuit breaker 1. As in FIG. 1, the circuit breaker 1 has a main current path L for conducting a main current between the network-side and the load-side connections LG, LL. The circuit breaker 1 has two normally on semiconductor actuators JF which are connected in antiseries in the main current path L and each also have, in addition to a source connection S and a drain connection D, a control connection G_JF for controlling the voltage of the normally on semiconductor actuators JF. The normally on semiconductor actuators JF are designed as JFETs. The two normally on semiconductor actuators JF form an HV switch 2.

The circuit breaker 1 has two normally off semiconductor actuators MF which are connected in antiseries in the main current path L and each also have, in addition to a source connection S and a drain connection D, a control connection G_MF for controlling the voltage of the normally off semiconductor actuator MF. The normally off semiconductor actuators MF are designed as MOSFETs. The two normally off semiconductor actuators MF are connected directly next to one another and form an LV switch 4.

The power electronics part of the circuit breaker 1 is thus separated into an HV part and an LV part. The HV part includes the two JFETs JF and the LV part includes the two MOSFETs MF. In contrast to the circuit shown in FIG. 1, only the normally off semiconductor actuators MF, which form the LV switch 4, are connected in pairs in antiseries with one another; by contrast, the two normally on semiconductor actuators JF are arranged on both sides of the LV switch 4, that is to say the LV switch 4 is surrounded by the two normally on semiconductor actuators JF in the main current path L. The HV switch 2 thus has a first HV part switch 2.1, that is to say a first normally on semiconductor actuator JF arranged between the network-side connection LG and the LV switch 4 in the main current path L, and a second HV part switch 2.2, that is to say a second normally on semiconductor actuator JF arranged between the load-side connection LL and the LV switch 4 in the main current path L.

The circuit breaker 1 has a charge store C in the form of a capacitor, which is connected to the normally off semiconductor actuators MF and can be charged by blocking the main current by means of the normally off semiconductor actuators MF and, in the charged state, provides a supply voltage U_{elec}for operating the circuit breaker 1. A first connection C.1 of the charge store C is electrically connected to a potential reference point P (ground) which lies between the two normally off semiconductor actuators MF. A second connection C.2 of the charge store C is electrically connected to two contact points 26, 26', which are each located between the LV switch 4 and one of the two normally on semiconductor actuators JF. In order to prevent discharge of the charge store C, a diode 10 is respectively arranged in the electrical lines 28, 28’ that connect the second connection C.2 of the charge store C to the main current path L.

The circuit breaker 1 has a control unit CU for controlling the voltage of the semiconductor actuators JF, MF. In this case, the charge store C, in the charged state, provides a supply voltage Uelec for the control unit CU and for controlling the voltage of the semiconductor actuators JF, MF. The control unit CU has a digital computing unit 31, for example a microprocessor, and a data memory 32 in which a computer program product is stored. The computer program product can be loaded directly into the internal memory of the digital computing unit 31; it comprises software code sections which cause the circuit breaker 1 according to the invention to carry out the method steps of the method described herein when the computer program product runs on the digital computing unit 31.

The circuit breaker 1 has a current measuring apparatus 6 in the main current path L. The current measuring apparatus 6 is arranged in the main current path L between the load-side connection LL and the second HV part switch 2.2. The current measuring apparatus 6 has a current measuring resistor 8. Current values determined by the current measuring apparatus 6 are transmitted to the control unit CU by way of a data transmission path 14. In the control unit CU, control commands for controlling the voltage of the semiconductor actuators JF, MF are generated on the basis of the received current values and are transmitted to the semiconductor actuators JF, MF by way of the control paths 16, 18. The voltage for operating the control unit CU and for controlling the voltage of the HV switch 2 and the LV switch 4 is provided by the supply voltage Uelec stored in the charge store C.

Unidirectional breakdown diodes 12 are respectively connected in parallel with the LV switch 4 having the normally off semiconductor actuators MF and the normally on semiconductor actuators JF. In addition, each of the normally off semiconductor actuators MF has a body diode 11.

The circuit breaker 1 also has a current measuring apparatus 6 in the main current path L. The current measuring apparatus 6 is arranged in the main current path L between the load-side connection LL and the second HV part switch 2.2. The current measuring apparatus 6 has a current measuring resistor 8. Current values determined by the current measuring apparatus 6 are transmitted to the control unit CU by way of a data transmission path 14. In the control unit CU, control commands for controlling the voltage of the semiconductor actuators JF, MF are generated on the basis of the received current values and are transmitted to the semiconductor actuators JF, MF by way of the control paths 16, 18. These control commands are implemented as control voltages which are applied to the control connections G_JF and G_MF of the semiconductor actuators JF, MF. The voltage for operating the control unit CU and for controlling the voltage of the HV switch 2, 2.1, 2.2 and the LV switch 4 is provided by the supply voltage Uelec stored in the charge store C.

The circuit breaker 1 also has two switching elements S1, by means of which the charge store C can be electrically connected to the control connections G_JF of the normally on semiconductor actuators JF or can be disconnected therefrom. In this case, the switching elements S1 can be actuated by the control unit CU via control paths 20. Since the switching elements S1 are designed as electronic contacts, namely as transistors, the control unit CU can control the switching elements S1 by means of a control signal via the control paths 20. If the switching elements S1 are in a conducting or low-impedance switching state, the normally on semiconductor actuators JF and the normally off semiconductor actuators MF are connected in a manner known in the literature as a cascode circuit: if the normally off semiconductor actuators MF are blocking, the normally on semiconductor actuators JF also enter a blocking state. If the switching elements S1 are in a blocking or high-impedance switching state, the normally on semiconductor actuators JF are in a permanently conducting state and the normally off semiconductor actuators MF can be controlled independently of the normally on semiconductor actuators JF.

The circuit breaker 1 also has two electrical resistors 9. A first electrical connection of these resistors 9 is connected to the main current path L, specifically at a contact point 26, 26' which lies between the first and/or second HV part switches 2.1, 2.2 and the LV switch 4. A second electrical connection of these resistors 9 is connected to a contact point 27, 27' which lies between the control connections G_JF of the normally on semiconductor actuators JF and the potential reference point P.

The advantage of the connection shown in FIG. 2, in which the normally off semiconductor actuators MF are surrounded by the normally on semiconductor actuators JF, is that the supply voltage Uelec generated in the charge store C has a fixed potential reference through the circuit, in which the potential reference point P (ground) lies between the two normally on semiconductor actuators JF; the potentials are thus suitable for controlling the control connections G_JF (gate) of the normally on semiconductor actuators JF.

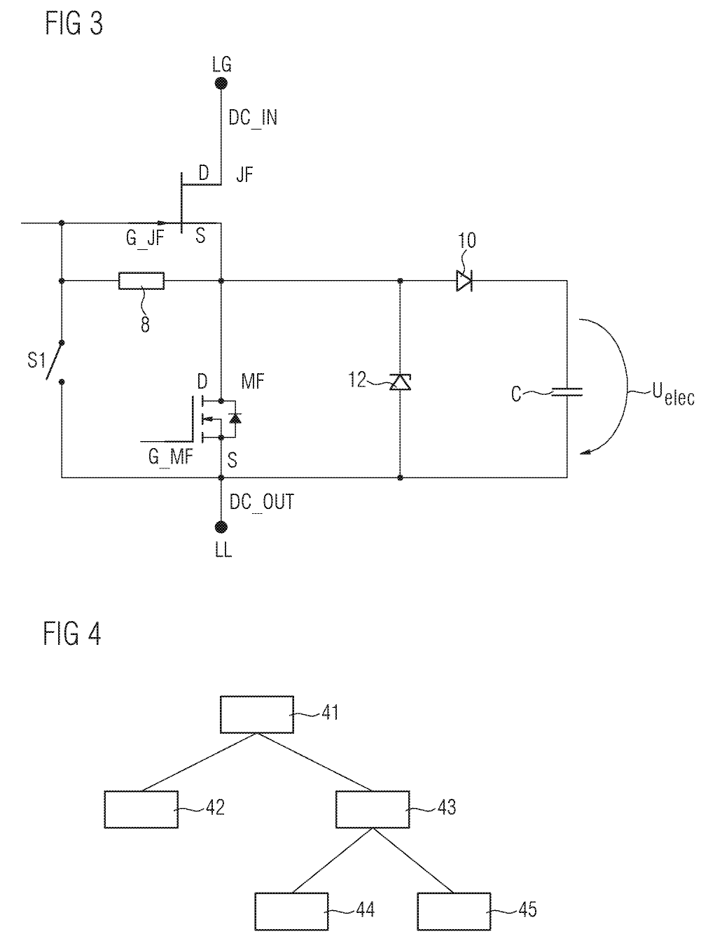

FIG. 3 is a simplified illustration of FIG. 2. The various operating modes described in FIGS. 4 to 9 are explained with reference to FIG. 3. FIG. 3 shows only "the upper half" of FIG. 2; for the sake of simplification and clarity, the illustration of some components which are obvious to a person skilled in the art, such as diodes 11, 12, and implicit components, such as a control unit for controlling the semiconductor actuators JF, MF and a current measuring apparatus for detecting a fault (overcurrent, short circuit) in the main current path L, has been dispensed with. With regard to the description of the circuit, reference is made to the description of FIG. 2, which applies analogously here. The circuit shown in FIG. 3 could be used in a unidirectional DC application. In this case, an input direct current DC_IN would flow from the network-side connection LG in the direction of the normally on semiconductor actuator JF and an output direct current DC_OUT would flow from the normally off semiconductor actuator MF in the direction of the load-side connection LL.

FIG. 4 shows an overview of different operating modes. The box 41 symbolizes all connections of two JFETs and two MOSFETs in a main current path. The box 42 symbolizes, as a subset of 41, the connections in which, according to FIG. 1, the normally off semiconductor actuators MF and the normally on semiconductor actuators JF are each connected directly next to one another. The box 43 symbolizes, as a subset of 41, the connections in which, according to FIG. 2, the normally off semiconductor actuators MF are connected between the normally on semiconductor actuators JF.

The box 44 symbolizes, as a subset of 43, an operating mode A in which the circuit breaker 1 transitions directly (by itself) to a conducting state: the circuit breaker 1 automatically reaches a state in which the normally on semiconductor actuators JF permit a current through the main current path L.

The box 45 symbolizes, as a subset of 43, an operating mode B in which the circuit breaker 1 transitions to a conducting state only after a release (a control command): the circuit breaker 1 automatically reaches a safe state in which the normally on semiconductor actuators JF block the main current path L.

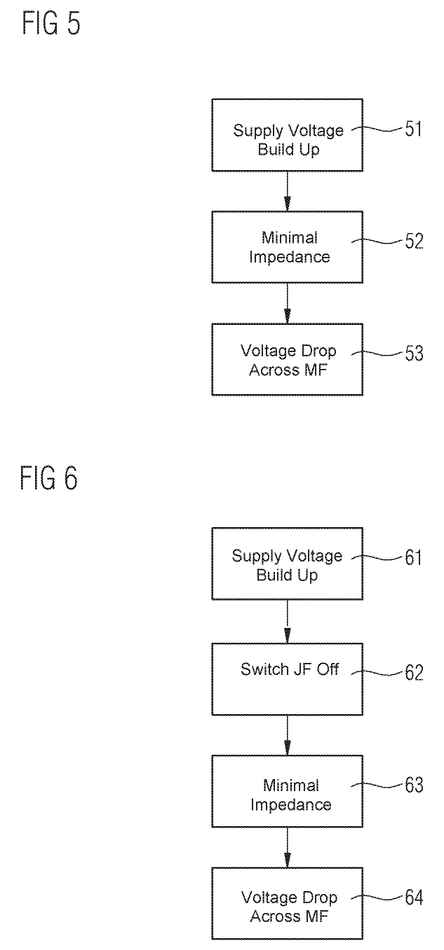

FIGS. 5-6 show the processes when there is formation of a network and a significant load is present (= standard case).

FIG. 5 shows the process when there is formation of the network and a significant load in mode A which transitions directly to a conducting state. The term "formation of the network" means that there is network voltage or voltage on the network side.

Step 51: At the beginning, the HV switch JF is conducting, the LV switch MF is blocking and the switch S1 is blocking. A main current flows through the circuit breaker 1 as a result of the load at the load-side connection LL (HV switch JF is conducting). In the LV switch MF, the main current flows into the capacitor C and builds up a supply voltage Uelec.

Step 52: As soon as the supply voltage Uelec in the capacitor C has reached a level sufficient for the voltage supply, for example 25 V, the LV switch MF is switched on. As a result, the main current can flow through the circuit breaker 1 with minimal impedance.

Step 53: If the supply voltage Uelec drops below a defined threshold due to discharge, the LV switch MF is brought into the blocking state for a defined period of time; the duration of the period of time (switch-off pulse) can be selected on the basis of the main current. This results in a voltage drop across the LV switch MF and thus in renewed charging of the capacitor C. If the supply voltage Uelec in the capacitor C is again high enough for the voltage supply, the LV switch MF is switched into the conducting state again.

Steps 51-53 can be implemented as instructions in a computer program product that cause the circuit breaker to carry out the method steps.

FIG. 6 shows the process when there is formation of the network and a significant load in mode B which transitions to a conducting state only after release.

Step 61: At the beginning, the HV switch JF is conducting, the LV switch MF is blocking and the switch S1 is conducting. A main current flows through the circuit breaker 1 as a result of the load at the load-side connection LL (HV switch JF is conducting). In the LV switch MF, the main current flows into the capacitor C and builds up a supply voltage Uelec.

Step 62: As soon as the supply voltage Uelec in the capacitor C has reached a level sufficient for the voltage supply, for example 25 V, the HV switch JF is switched off automatically by the supply voltage applied to its gate. The LV switch MF is also still blocking. The mode thus automatically reaches a safe state.

Step 63: In the case of a release of any kind, whether it be internal, for example when the entire system is ready for use, or external, for example as a result of a switching request, the switch S1 is switched to high impedance and the LV switch MF is switched on. By switching the switch S1 to a high-impedance state, the HV switch JF becomes normally on. The main current can now flow with minimal impedance.

Step 64: If the supply voltage Uelec drops below a defined threshold (discharge), the LV switch MF is brought into the blocking state for a defined period of time; the duration of the period of time (switch-off pulse) can be selected on the basis of the main current. This results in a voltage drop across the LV switch MF and thus in renewed charging of the capacitor C. If the supply voltage Uelec in the capacitor C is high enough for the voltage supply, the LV switch MF is switched into the conducting state again.

Steps 61-64 can be implemented as instructions in a computer program product that cause the circuit breaker to carry out the method steps.

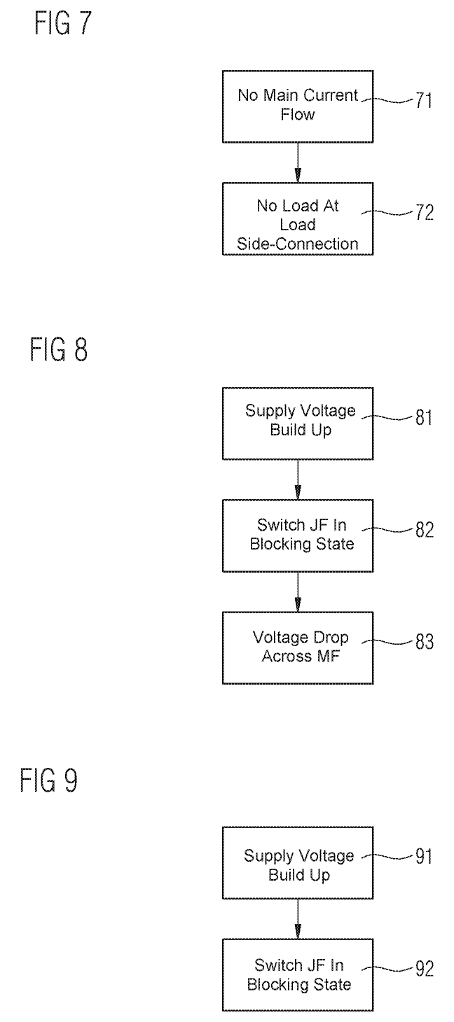

FIG. 7 shows the process when there is formation of the network and no load, both for mode A and for mode B.

Step 71: First, the HV switch JF is conducting and the LV switch MF is blocking. Since no load is connected to the load-side connection LL, the connections LG, LL are at the same electrical potential and no main current flows through the circuit breaker 1. Thus, the voltage drop across the LV switch MF is also absent.

Step 72: As soon as a load is present at the load-side connection LL, the method steps proceed as described above in FIGS. 5 and 6.

Steps 71-72 can be implemented as instructions in a computer program product that cause the circuit breaker to carry out the method steps.

FIGS. 8-9 show the processes when there is formation of the network and a short circuit.

FIG. 8 shows the process when there is formation of the network and a short circuit for mode A which transitions directly to a conducting state.

Step 81: At the beginning, the HV switch JF is conducting, the LV switch MF is blocking and the switch S1 is blocking. A main current flows through the circuit breaker 1 as a result of the load at the load-side connection LL (HV switch JF is conducting). In the LV switch MF, the main current flows into the capacitor C and builds up a supply voltage Uelec.

Step 82: Since the main current can rise to a multiple of the rated current within several 10 µs due to the short circuit and the current measurement in the main circuit detects this current behavior, instead of switching the LV switch MF on, the HV switch JF is brought into the blocking state, be it by switching the switch S1 to a low-impedance state (cascode circuit) or by controlling the gate of the HV switch JF by means of the supply voltage.

Step 83: If the supply voltage Uelec drops below a defined threshold (discharge), the HV switch JF is brought into the conducting state for a defined period of time; the duration of the period of time (switch-off pulse) can be selected on the basis of the main current. This results in a voltage drop across the LV switch MF and thus in renewed charging of the capacitor C. If the supply voltage Uelec in the capacitor C is high enough for the voltage supply, the HV switch JF is switched into the blocking state again.

The challenge in this operating mode is that, in particular when connecting to the short circuit, it must be ensured that the reaction chain (e.g. voltage present, current measurement active, switch-off command output) is fast enough.

Steps 81-83 can be implemented as instructions in a computer program product that cause the circuit breaker to carry out the method steps.

FIG. 9 shows the process when there is formation of the network and a short circuit for mode B which transitions to a conducting state only after release.

Step 91: At the beginning, the HV switch JF is conducting, the LV switch MF is blocking and the switch S1 has a low impedance (= conducting). Network voltage builds up and a relatively high main current, which can be a multiple of the rated current due to the short circuit, flows through the switch (HV switch JF is conducting). In the LV switch MF, the main current flows into the capacitor C and builds up the supply voltage Uelec.

Step 92: Since the switch S1 is kept at low impedance, the HV switch JF is brought into a blocking state immediately upon the build-up of the supply voltage Uelec, since it is connected as in a cascode circuit.

Steps 91-92 can be implemented as instructions in a computer program product that cause the circuit breaker to carry out the method steps.

The embodiment shows that, in mode B "mode which transitions to a conducting state only after release", there are no challenges with regard to the timing during short-circuit disconnection. As soon as a supply voltage is present in the capacitor C, the HV switch JF goes into the blocking mode due to the cascode circuit and thus establishes a safe state of the circuit breaker. Therefore, mode B is to be preferred from a "safety" point of view.

The following is a summary list of reference numerals and the corresponding structure used in the above description of the invention:
1 SSCB 2 HV switch
2.1 HV switch
2.2 HV switch
4 LV switch
6 Current measuring apparatus
8 Current measuring resistor
9 Resistor, electrical
10 Diode
11 Diode, body diode, intrinsic diode
12 Zener diode
13 Schottky diode
14 Data transmission path
16 Control path
18 Control path
20 Control path
22 Contact point
22' Contact point
24 Contact point
24' Contact point
26 Contact point
26' Contact point
27 Contact point
27' Contact point
28 Line, electrical
28' Line, electrical
31 Digital computing unit, microcontroller
32 Data memory
41 Box
42 Box
43 Box
44 Box
51 Step
52 Step
53 Step
61 Step
62 Step
63 Step
64 Step
71 Step
72 Step
81 Step
82 Step
83 Step
91 Step
92 Step
C Electrical charge store
C.1 First connection of C
C.2 Second connection of C
CU Control unit
D Drain connection
G_JF Control connection of JF
G_MF Control connection of MF
JF Normally on semiconductor actuator
L Main current path
LG Network-side connection
LL Load-side connection
MF Normally off semiconductor actuator
P Potential reference point
S Source connection U_{elec} Electrical voltage of C

1. A solid state circuit breaker, comprising:
at least one network-side connection and at least one load-side connection;
a main current path for conducting a main current between said at least one network-side connection and said at least one load-side connections;
two normally-on semiconductor actuators being connected in antiseries in said main current path, each of said two normally-on semiconductor actuators having a control connection for controlling a voltage of said two normally-on semiconductor actuators;
two normally-off semiconductor actuators being connected in antiseries in said main current path, each of said two normally-off semiconductor actuators having a control connection for controlling a voltage of said two normally-off semiconductor actuators; and
a charge store connected in parallel with said two normally-off semiconductor actuators, said charge store being configured to be charged by blocking the main current by means of said two normally-off semiconductor actuators and in a charged state, to provide a supply voltage for operating the circuit breaker.

2. The solid state circuit breaker according to claim 1, further comprising a controller for controlling said voltage of said two normally-on semiconductor actuators and said two normally-off semiconductor actuators, wherein said charge store in the charged state provides a supply voltage for said controller and for controlling the voltage of said two normally-on semiconductor actuators and said two normally-off semiconductor actuators.

3. The solid state circuit breaker according to claim 1, wherein said two normally-off semiconductor actuators are connected between said two normally-on semiconductor actuators.

4. The solid state circuit breaker according to claim 1, wherein said two normally-off semiconductor actuators and said two normally-on semiconductor actuators are each connected in series in pairs in antiseries.

5. The solid state circuit breaker according to claim 1, further comprising a current measuring apparatus in the main current path.

6. The solid state circuit breaker according to claim 1, further comprising at least one switch, and said charge store can be electrically connected to said control connections of said normally-on semiconductor actuators, or can be disconnected therefrom, via said at least one switch.

7. The solid state circuit breaker according to claim 6, wherein said at least one switch can be actuated by said controller.

8. A method for operating a solid state circuit breaker, the method comprising:
conducting a main current through the main current path which electrically connects at least one network-side connection and at least one load-side connection of the circuit breaker, the main current being provided by a voltage applied between the network-side connection and load-side connection, and two normally-on semiconductor actuators being connected in antiseries in a main current path of the circuit breaker;
charging a charge store by the main current by blocking the main current with two normally-off semiconductor actuators, the charge store being connected in parallel with the two normally-off semiconductor actuators connected in antiseries in the main current path; and
reaching a charged state of the charge store, in which the charge store provides a supply voltage for operating the circuit breaker; and
operating the circuit breaker with the supply voltage provided by the charge store.

9. The method according to claim 8, further comprising operating a controller configured to control the voltage of the two normally-on semiconductor actuators and the two normally-off semiconductor actuators, and/or the two normally-on semiconductor actuators and/or the two normally-off semiconductor actuators via the supply voltage provided by the charge store.

10. The method according to claim 8, further comprising bringing the two normally-off semiconductor actuators from a conducting state into a blocking state to charge the charge store above a defined critical threshold value if the supply voltage drops below the defined critical threshold value.

11. The method according to claim 10, wherein the length of a period of time during which the normally-off semiconductor actuators are in a blocking state for charging the charge store is based on the main current and loads connected to the charge store.

12. The method according to claim 8, wherein the two normally-on semiconductor actuators are connected to the two normally-off semiconductor actuators in a cascode circuit such that the two normally-on semiconductor actuators are configured to change to the blocking state as soon as the charge store has built up a supply voltage which is sufficient to control the normally-on semiconductor actuators.

13. The method according to claim 8, wherein when a short-circuit current is detected in the main current path, the charge store charged to a supply voltage sufficient to control the two normally-on semiconductor actuators is electrically connected to control connections of the two normally-on semiconductor actuators by a switch, such that the normally-on semiconductor actuators change to the blocking state.

14. A computer program product comprising a non-transitory computer-readable medium storing instructions that, when executed by a processor, cause the processor to perform the method according to claim 8.

15. A computer-readable medium on which a computer program product stores instructions that, when executed by a processor, cause the processor to perform the method according to claim 8.
